(19) United States
(12) Patent Application Publication
(10) Pub. No.: US 2011/0194269 A1
(43) Pub. Date: Aug. 11, 2011

(54) CONNECTION ASSEMBLY WITH FRONT CABLING FOR AT LEAST ONE ITEM OF ELECTRONIC EQUIPMENT IN AN AIRCRAFT

(75) Inventors: Emile COLONGO, Montesquieu Volvestre (FR); Pierre Salles, La Salvetat St. Gilles (FR)

(73) Assignee: AIRBUS OPERATIONS (S.A.S.), Toulouse (FR)

(21) Appl. No.: 13/021,511

(22) Filed: Feb. 4, 2011

(30) Foreign Application Priority Data
Feb. 5, 2010 (FR) 10 50838

(51) Int. Cl. H05K 7/00

(52) U.S. Cl. 361/807

(57) ABSTRACT

The invention relates to a connection assembly (1) for at least one item of electronic equipment (2) to the wiring (3) of an aircraft, in which the said at least one item of electronic equipment (2) is disposed in a support means (4) and comprises connection means able to be connected to the wiring (3) of the aircraft through at least one connection interface (6), characterized in that the said at least one connection interface (6) is connected to the wiring (3) through a wiring box (30) interposed between the said interface (6) and the wiring (3), the said wiring box (30) being disposed in the support means (4) to provide the connection between the connection interface (6) and the wiring (3) through the said support means (4), the support means (4) comprising a front face (16) and a rear face (18) on which the said at least one connection interface (6) is disposed, the connection assembly (1) comprising a cable passage (31) in which the wiring (3) is disposed and which extends to the vicinity of the front face (16) of the support means.

This invention relates to a connection assembly for at least one item of electronic equipment in an aircraft.

In an aircraft, many items of electronic equipment are concentrated in a zone located underneath the cockpit of the aircraft, which provides the items of equipment with preferential environmental conditions such as reasonable ambient pressure and a controlled ambient temperature. Support means are disposed in this zone and make it possible to fasten the items of equipment, connect them to the cables of the aircraft and ventilate them.

The document US2004050569 describes and shows a known connection assembly, in which at least one item of electronic equipment is disposed in a support means. The support means is added onto a movable carrier structure. The carrier structure comprises a connection interface on which the support means comes to be connected. The assembly formed in this way is brought into the desired zone, alongside other assemblies formed separately and the wiring of the aircraft is added onto each connection interface integral with a support means.

The invention is intended to propose a connection assembly for an item of electronic equipment simplified in comparison with the prior art, particularly in the installation, wiring and subsequent maintenance operations of the electronic assembly.

For this purpose, the invention has as an object an assembly for connection of at least one item of electronic equipment to the wiring of an aircraft, in which the said at least one item of electronic equipment is disposed in a support means and comprises connection means able to be connected to the wiring of the aircraft through at least one connection interface, characterized in that the said at least one connection interface is connected to the wiring through a wiring box interposed between the said interface and the wiring, the said wiring box being disposed in the support means in order to provide the connection between the connection interface and the wiring through the said support means, the support means comprising a front face and a rear face on which the said at least one connection interface is disposed, the connection assembly comprising a cable passage in which the wiring is disposed and which extends to the vicinity of the front face of the support means.

Such a connection assembly advantageously makes it possible to reduce the space requirement for the wiring of the aircraft as a result of the integration of a part of this wiring into modules incorporated into the support means. It allows a simplified layout of the zones of the aircraft in which items of electronic equipment are to be connected to the wiring.

Moreover, the presence of a cable passage at the front face of the support means makes it possible in particular to protect the cables during possible handling by an operator and to prevent the latter from tripping over the wiring. In fact, the edges of this front face are likely to be involved more during handling. The fact of gathering the cables together also saves a significant amount of space, which is useful at the front face of the support means. Finally, the cable passage makes it possible to conceal the cables, which is agreeable from an esthetic point of view.

This arrangement at the front face makes the connection of the wiring of the aircraft simpler to implement and inspect (by virtue of making the connections visible). Furthermore, possible modifications to be made to the connection, or even to the wiring itself, are simpler to implement. According to various characteristics:
The support means comprises at least one module with more or less rectangular section, the back of which is opposite the connection interface, and the front face of which is open, the said at least one item of electronic equipment and the wiring box being adapted for being inserted into the said at least one module.
The said at least one module is adapted for accommodating at least one item of electronic equipment and a sole wiring box.
The wiring box is connected by one end to the wiring of the aircraft in the vicinity of the front face of the said at least one module, the opposite end of the said wiring box being connected in the back of the said at least one module to the said at least one connection interface.
The support means comprises several modules disposed one on top of the other.
The said at least one connection interface is integrated into the support means.
Two support means are disposed side by side, a sole cable passage extending to the vicinity of the two support means.
The cabinet has a built-in cooling system; the cooling system for the cabinet is autonomous, or interconnected with the cooling system of the aircraft.
The said at least one connection interface extends more or less vertically along the structure of the aircraft.
The cable passage comprises a box in which the wiring is disposed.
The wiring is disposed vertically, the box extending vertically.
The box is provided with holes so that the cables or cable bundles making up the wiring emerge from the box through the holes with a view to their connection to one or more wiring boxes disposed more or less in the vicinity of the holes.
The box is disposed on top of an opening made in a surface (for example the floor) on which the connection assembly rests. The wiring of the aircraft thus goes through the opening to enter the box.
Guidance means are disposed on the structure of the aircraft, to guide the support means in relation to the connection interface.

The invention also concerns an aircraft comprising at least one connection assembly for an item of electronic equipment according to the invention.

The characteristics and advantages of the invention will become apparent from the description that follows, provided by way of preferred, but not limitative, example, with reference to the attached drawings on which:

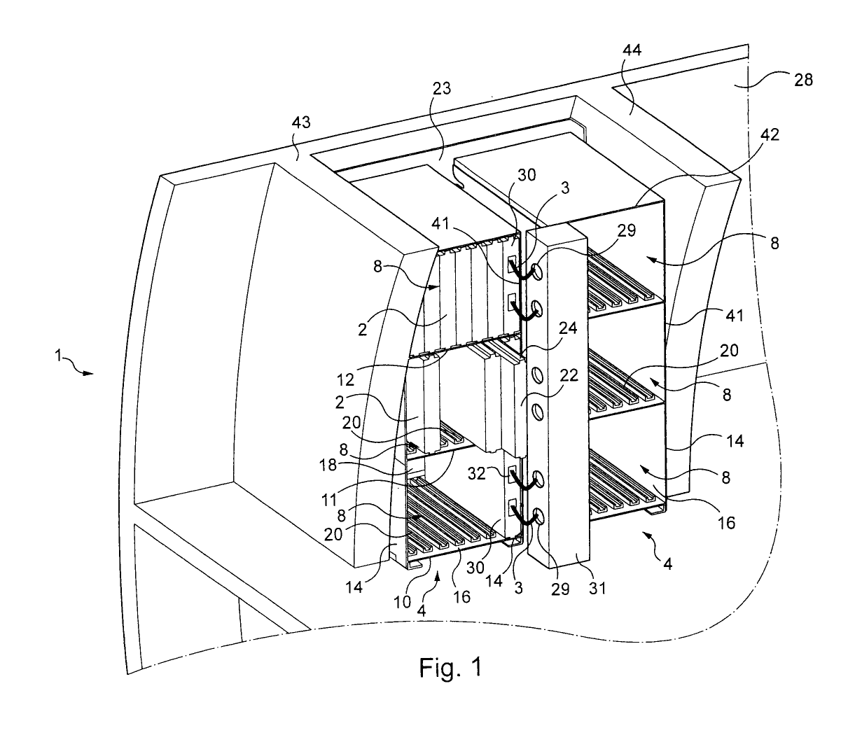

FIG. 1 is a depiction of a connection assembly according to the invention;

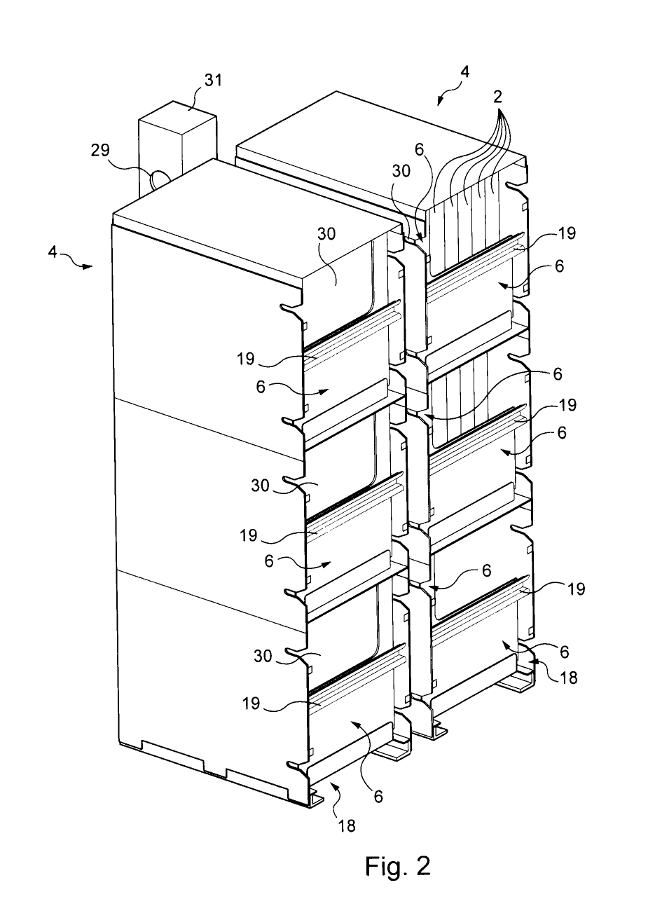

FIG. 2 is a schematic depiction of the support means, three-quarter rear view;

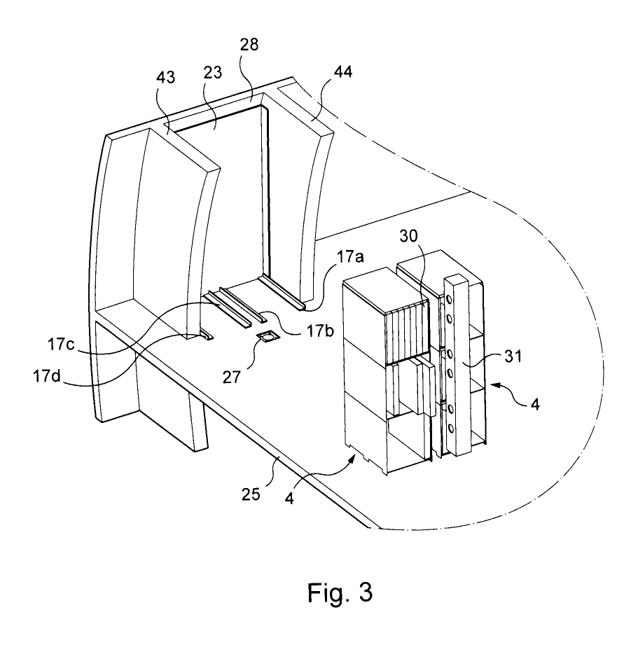

FIG. 3 is a depiction of the connection assembly of FIG. 1, in an alternative position in which the support means is recessed in relation to the structure of the aircraft.

Connection assembly 1 for an item of electronic equipment 2 comprises at least one support means 4 and a connection interface 6. Connection assembly 1 is disposed in an aircraft, and provides the connection for an item of electronic equipment 2 to wiring 3 of the aircraft.

Support means 4 forms as it were a cabinet that comprises modules 8 with more or less rectangular section. Each cabinet 4 comprises, for example, a lower rack 10, an intermediate rack 11 and an upper rack 12, connected by two side walls 14, which thus define a front face 16 and a rear face 18. The front face and the rear face of each module are open, without walls in order to facilitate access and handling.

As illustrated, here three modules 8 are stacked one on the other, to form a support means 4 of given height. Moreover, here, two support means 4 are disposed side by side. Six modules 8 have the same dimensions and are aligned, so that each rear face 18 is included in the same vertical plane.

It will be noted that each support means 4 may comprise a number of modules other than three and more than two means may be disposed adjacently.

Means forming slide 20 are arranged on the faces opposite lower rack 10, intermediate rack 11 and upper rack 12 of the same module 8.

Each module 8 is adapted for accommodating at least one item of electronic equipment 2 and a wiring box 30. Item of electronic equipment 2 and wiring box 30 of each module 8 are disposed, for example, vertically on each of lower 10, intermediate 11 and upper 12 racks of the said cabinet 4.

Item of electronic equipment 2 comprises a protective cove 22. The cover comprises ribs 24 forming complementary guidance means adapted for cooperating with the means forming slides 20 arranged on the faces opposite the racks of support means 4. Said ribs 24 extend axially over an upper face and a lower face of cover 22.

Item of electronic equipment 2 further comprises first connection means, on a face of its cover 22 perpendicular to its upper and lower faces and perpendicular to the axial direction of extension of the ribs. When each item of electronic equipment 2 is inserted into a module 8 of support means 4, the said first connection means of each item of electronic equipment emerge on rear face 18 of said module 8.

Wiring box 30 comprises a protective cover that has dimensions equivalent to the dimensions of cover 22 of item of electronic equipment 2. Wiring box 30 comprises complementary guidance means (not visible on the Figures) adapted for cooperating with the means forming slides 20 arranged on the faces opposite the racks of support means 4. Two opposite faces referred to as front and rear of this wiring box comprise connection means for wiring 32, so that when wiring box 30 is inserted into a module 8 of support means 4, the said wiring connection means emerge on front face 16 and on rear face 18 of said module 8.

The opposite front and rear faces of wiring box 30 are arranged perpendicular to the direction of insertion of the box into the module and perpendicular to the faces of the box that comprise the complementary guidance means.

At least one connection interface 6 is provided for the connection of the wiring of the aircraft to the first connection means of items of electronic equipment 2 borne by modules 8 of support means 4.

It is conceivable, for example, to have one connection interface per module. Alternatively, an interface could be shared by several modules.

Such a connection interface is implemented, for example, in the form of an electronic card, more or less plane, installed at rear face 18 of the cabinet (FIG. 2).

The interface has, for example, an L shape which is adapted to the arrangement of wiring box 30 and items of electronic equipment 2 in each module. Insofar as there is a greater number of connection/wiring points between wiring box 30 and the interface than between the items of electronic equipment and the interface, the latter extends along more or less the entire measure of the rear face of the wiring box but not along the entire rear face of items of electronic equipment 2.

This is why the interface reaches only halfway up this rear face as shown on FIG. 2. Moreover, this arrangement of the interface reduces the weight of the assembly.

The interface thus has an L shape the vertical branch of which is opposite the rear face of wiring box 30, while the horizontal branch is opposite only a part of the rear face of items of electronic equipment 2. Other interface shapes are conceivable depending on the arrangement of the elements in modules 8, according to the connection requirements and the elements (nature, form, number . . . ).

Each connection interface 6 is positioned more or less to the right of rear face 18 of modules 8 (it is integral with each module 8) and has second connection means (not shown on FIG. 2 because they are turned toward the inside of each module) which in part are adapted for being connected to the first connection means borne by items of electronic equipment 2. A second part of these second connection means also is adapted for being connected to the connection means for wiring 32 (connectors) of wiring box 30 which are arranged on the rear face of the latter.

According to a variant not shown, connection interface 6 is fastened to structure 28 of the aircraft.

As illustrated, support means 4 comprises two vertical side edges 41 formed by the respective side walls of superposed modules 8, and a horizontal upper edge 42 formed by the upper rack of the module disposed at the top of support means 4.

A cable passage or guide 31 is formed in a box in which cables or cable bundles 3 of the aircraft are disposed. Here, cable passage 31 extends vertically, along a vertical side edge 41 of support means 4. As a variant, said cable passage 31 extends horizontally along horizontal upper edge 42 of the support means.

According to other variants, the horizontal box is fastened to a vertical wall of the aircraft from which the wiring emerges, or is connected to another vertical box which is provided with an internal opening at the connection so as to form an overall box in the shape of an inverted L. In any case, cable passage 31 extends to the vicinity of front face 16 of support means 4, said cable passage 31 being connected to wiring box 30 close to this front face 16 of support means 4.

The installation and use of such a connection assembly now is going to be described.

First, a vertical upright 23 is fastened against structure 28 of the aircraft and guidance rails 17a, 17b, 17c, 17d (that is, two pairs, one pair for each cabinet) are fastened to floor 25 of the aircraft, perpendicular to upright 23 (FIG. 3).

A connection interface 6 is installed in each module 8 of a first support means 4 (first cabinet) at the rear face 18 and stringers 19 are installed between the side walls of the modules.

The three modules 8 are installed one on top of the other.

First support means 4 is brought against upright 23 of structure 28 of the aircraft, close to an opening 27 made in floor 25 in order to allow the crossing of cables of the wiring of the aircraft and is, for example, made integral with structure 28. During this installation of the first support means, item of electronic equipment 2 and wiring box 30 already are in place in support means 4. As a variant, the support means is brought against structure 28, and the items of electronic equipment and the wiring boxes are inserted into the support means afterwards.

In these two cases it will be noted that the establishment of the connections, on the one hand, between items of electronic equipment 2 and connection interface 6 and, on the other hand, between wiring box 30 and connection interface 6 may be implemented very simply “blindly”: each of units 2 and 30 is inserted inside a module until coming into contact at the back with the interface, thus fitting together the male connectors of one of the elements with the female connectors of the other element. The establishment of electrical connections thus is accomplished simply in this way.

It will be noted that a mechanical locking of the units with the interface also may be implemented.

First support means 4 may comprise means able to facilitate its movement, not shown, such as casters, or gripping means for a maintenance device.

Guidance in translation is facilitated by the presence of guidance means disposed in the vicinity of structure 28. As illustrated, these guidance means here are vertical walls 43, 44, integral with structure 28 of the aircraft and which extend perpendicular toward the inside of the aircraft starting from this structure. These walls surround upright 23.

First support means 4 is disposed along a first direction between side structure 28 of the aircraft and cable passage 31 and along a second perpendicular direction between said cable passage 31 and a first wall 43 of structure 28.

A second support means 4 (second cabinet) similarly is brought against upright 23 of structure 28. The second support means is disposed along a first direction between side structure 28 and cable passage 31, and along a second perpendicular direction, between said cable passage 31 and a second wall 44 of structure 28.

The two support means 4 here are positioned side by side so that cable passage 31 extends to the vicinity of the front face of each support means and for example, more precisely, to the vicinity of a vertical side edge 41.

Box 31, also called sleeve, is installed above opening 27 and traversing cable bundles 3 are installed inside the box and are positioned appropriately at the various holes 29 provided in the box to emerge from the said box through the latter with a view to their connection.

The holes are made, for example, over more or less the entire height of the box (or alternatively along a part of the height) so as to distribute the cable bundles at different heights for different modules 8. Holes 29 are implemented, for example, on two opposite faces of the box only one face of which is visible on FIGS. 1 and 3.

Alternatively, holes could be made on each face to facilitate installation of the box on the floor.

Consequently the cable bundles provided with their connectors emerge outside the holes of the box and hang along the latter, ready for connection.

Cable bundles 3 from cable passage 31 then are connected at a first end (front face) of at least one wiring box 30, through connection means to wiring 32 (connectors) borne by this first end and which emerge on front face 16 of module 8 (FIG. 1).

Since the other end (rear face) of this wiring box 30 is connected to connection interface 6, a connection of items of electronic equipment 2 to wiring 3 of the aircraft thus is achieved through, successively, a connection interface 6 and a wiring box 30.

Furthermore, in the example a cable guide is shared by two cabinets and, alternatively, could be used with more than two cabinets depending on the form, and the dimensions of the cable guide and depending on the arrangement of the latter in relation to the cabinets. It will be noted that wiring boxes 30 are disposed in support means 4, so that the connection between connection interface 6 and wiring 3 of the aircraft is provided through said support means 4.

1. Connection assembly (1) for at least one item of electronic equipment (2) to the wiring (3) of an aircraft, in which the said at least one item of electronic equipment (2) is disposed in a support means (4) and comprises connection means able to be connected to the wiring (3) of the aircraft through at least one connection interface (6), characterized in that the said at least one connection interface (6) is connected to the wiring (3) through a wiring box (30) interposed between the said interface (6) and the wiring (3), the said wiring box (30) being disposed in the support means (4) to provide the connection between the connection interface (6) and the wiring (3) through the said support means (4), the support means (4) comprising a front face (16) and a rear face (18) on which there is disposed at least one connection interface (6), the connection assembly (1) comprising a cable passage (31) in which the wiring (3) is disposed and which extends to the vicinity of the front face (16) of the support means.

2. Connection assembly according to claim 1, characterized in that the support means (4) comprises at least one module (8) with more or less rectangular section, the back of which is opposite the connection interface (6), and the front face (16) of which is open, the said at least one item of electronic equipment (2) and the wiring box (30) being adapted for being inserted into the said at least one module (8).

3. Connection assembly according to claim 2, characterized in that the said at least one module (8) is adapted for accommodating at least one item of electronic equipment (2) and a sole wiring box (30).

4. Connection assembly according to claim 2 or 3, characterized in that the wiring box (30) is connected by one end to the wiring (3) of the aircraft in the vicinity of the front face (16) of the said at least one module (8), the opposite end of the said wiring box (30) being connected in the back of the said at least one module (8) to the said at least one connection interface (6).

5. Connection assembly according to one of claims 2 to 4, characterized in that the support means (4) comprises several modules (8) disposed one on top of the other.

6. Connection assembly according to one of the preceding claims, characterized in that the said at least one connection interface (6) is integrated into the support means (4).

7. Connection assembly according to one of claims 1 to 6, characterized in that the cable passage (31) comprises a box in which the wiring is disposed.

8. Connection assembly according to claim 7, characterized in that the wiring is disposed vertically, the box extending vertically.

9. Connection assembly according to claim 7 or 8, characterized in that the box is provided with holes disposed so that the cables or cable bundles making up the wiring (3) emerge from the said box through the said holes with a view to their connection to at least one wiring box.

10. Connection assembly according to any one of claims 7 to 9, characterized in that the box (31) is disposed above an opening made in a surface on which the connection assembly rests.

11. Connection assembly according to one of claims 1 to 10, characterized in that two support means (4) are disposed side by side, a sole cable passage (31) extending to the vicinity of the two support means (4).

12. Aircraft characterized in that it comprises at least one connection assembly for an item of electronic equipment according to one of claims 1 to 11.
